(19) United States
(12) Patent Application Publication
(10) Pub. No.: US 2019/0050359 A1
(43) Pub. Date: Feb. 14, 2019

(54) SWITCHING DEVICE FOR FACILITATING COMMUNICATION OF DATA

(71) Applicants: Ricardo Velez-McCaskey, Nashua, NH (US); Michael Levine, Nashua, NH (US)

(72) Inventors: Ricardo Velez-McCaskey, Nashua, NH (US); Michael Levine, Nashua, NH (US)

(21) Appl. No.: 16/103,439

(22) Filed: Aug. 14, 2018

Related U.S. Application Data
(60) Provisional application No. 62/545,269, filed on Aug. 14, 2017.

(51) Int. Cl. G06F 13/40; H03K 17/00; H04L 29/06; H04L 29/12

(52) U.S. Cl. CPC G06F 13/4022; H03K 17/007; G06F 13/4282; H04L 61/2557; H04L 69/08

(57) ABSTRACT

Disclosed is a switching device for facilitating data communication between at least one initiator device and multiple target devices. The switching device includes at least one input port configured to receive data from the at least one initiator device. The at least one input port is communicatively coupled to at least one internal bus corresponding to the at least one initiator device. The switching device includes multiple output ports configured to transmit data to the multiple target devices. The multiple output ports are communicatively coupled to a multiple internal bus corresponding to the multiple target devices. The switching device includes at least one routing module communicatively coupled with each of the at least one input port and the multiple output ports. The at least one routing module is configured to route data from the at least one input port to at least one output port of the multiple output ports.

### FIELD OF THE INVENTION

The present invention relates generally relates to the field of data communication. More specifically, the present disclosure relates to a switching device for facilitating data communication between devices.

### BACKGROUND OF THE INVENTION

In computer architecture, a bus is a communication system that transfers data between components inside a computer. The bus covers all related hardware components (wire, optical fiber, etc.) and software, including communication protocols. For example, a Peripheral Component Interconnect Bus (PCI bus) connects the CPU and expansion boards such as modem cards, network cards and sound cards. Further, the multiple computing devices are often connected with each for various applications. When extending the PC Internal Express (PCIe) bus, devices like bridges or switches may be used. If communication with multiple computing devices connected to a switch is needed, the convention method includes multicasting by sending the information to all the ports in the switch. However, if an attached device does not request or require this information, this leads to unnecessary use of the bus (bandwidth). Further, multicast protocol does not warrantee that all data gets to the targets, making this technique unusable for storage applications. In storage applications, ensuring data integrity is essential.

Accordingly, there is a need for devices and systems with the ability to select the ports that are involved in a point-to-multipoint transfer and may overcome one or more of the abovementioned problems and/or limitations.

### SUMMARY

This summary is provided to introduce a selection of concepts in a simplified form that are further described below in the Detailed Description. This summary is not intended to identify key features or essential features of the claimed subject matter. Nor is this summary intended to be used to limit the claimed subject matter's scope.

According to an aspect, a switching device for facilitating communication of data between at least one initiator device and a plurality of target devices is disclosed. The switching device may include at least one input port configured to receive the data from the at least one initiator device. Further, the at least one input port may be communicatively coupled to at least one internal bus corresponding to the at least one initiator device. Further, the switching device may include a plurality of output ports configured to transmit data to the plurality of target devices. Further, the plurality of output ports may be communicatively coupled to a plurality of internal buses corresponding to the plurality of target devices. Further, the switching device may include at least one routing module communicatively coupled with each of the at least one input port and the plurality of output ports. Further, the at least one routing module may be configured to route the data from the at least one input port to at least one output port of the plurality of output ports.

According to another aspect, a switching device for facilitating communication of data between at least one initiator device and a plurality of target devices is disclosed. The switching device may include at least one input port configured to receive the data from the at least one initiator device. Further, the at least one input port may be communicatively coupled to at least one internal bus corresponding to the at least one initiator device. Further, the switching device may include a plurality of output ports configured to transmit data to the plurality of target devices. Further, the plurality of output ports may be communicatively coupled to a plurality of internal buses corresponding to the plurality of target devices. Further, the switching device may include at least one routing module coupled with each of the at least one input port and the plurality of output ports. Further, the at least one routing module may be configured to route the data from the at least one input port to at least one output port of the plurality of output ports. Further, the switching device may include at least one protocol conversion module communicatively coupled to each of the at least one routing module and the plurality of output ports. Further, the at least one protocol conversion module may be configured to convert the data from at least one first protocol associated with the at least one initiator device to at least one second protocol associated with at least one target device corresponding to the at least one output port.

According to another aspect, a switching device for facilitating communication of data between at least one initiator device and a plurality of target devices is disclosed. The switching device may include at least one input port configured to receive the data from the at least one initiator device. Further, the at least one input port may be communicatively coupled to at least one PCIe bus corresponding to the at least one initiator device. Further, the switching device may include a plurality of output ports configured to transmit data to the plurality of target devices. Further, the plurality of output ports may be communicatively coupled to a plurality of PCIe buses corresponding to the plurality of target devices. Further, the switching device may include at least one routing module communicatively coupled with each of the at least one input port and the plurality of output ports. Further, the at least one routing module may be configured to route the data from the at least one input port to at least one output port of the plurality of output ports.

Both the foregoing summary and the following detailed description provide examples and are explanatory only. Accordingly, the foregoing summary and the following detailed description should not be considered to be restrictive. Further, features or variations may be provided in addition to those set forth herein. For example, embodiments may be directed to various feature combinations and sub-combinations described in the detailed description.

### BRIEF DESCRIPTION OF THE DRAWINGS

The accompanying drawings, which are incorporated in and constitute a part of this disclosure, illustrate various embodiments of the present disclosure. The drawings contain representations of various trademarks and copyrights owned by the Applicants. In addition, the drawings may contain other marks owned by third parties and are being used for illustrative purposes only. All rights to various trademarks and copyrights represented herein, except those belonging to their respective owners, are vested in and the property of the applicants. The applicants retain and reserve all rights in their trademarks and copyrights included herein, and grant permission to reproduce the material only in connection with reproduction of the granted patent and for no other purpose.

Furthermore, the drawings may contain text or captions that may explain certain embodiments of the present disclosure. This text is included for illustrative, non-limiting, explanatory purposes of certain embodiments detailed in the present disclosure.

FIG. 1 is an illustration of a platform consistent with various embodiments of the present disclosure.

FIG. 2 is a block diagram of the switching device for facilitating communication of data between at least one initiator device and multiple target devices, in accordance with some embodiments.

FIG. 3 is a block diagram of a switching device for facilitating communication of data between at least one initiator device and multiple target devices, in accordance with some embodiments.

FIG. 4 is a block diagram of an OmniBUS PCIe Switch for facilitating communication of data, in accordance with some embodiments.

FIG. 5 is a block diagram of an OmniBUS PCIe Switch facilitating intelligent point-to-multipoint data transfer, in accordance with some embodiments.

FIG. 6 is a flowchart of a method of facilitating communication of data between at least one initiator device and multiple target devices, in accordance with some embodiments.

FIG. 7 is a block diagram of a computing device for implementing the methods disclosed herein, in accordance with some embodiments.

### DETAIL DESCRIPTIONS OF THE INVENTION

As a preliminary matter, it will readily be understood by one having ordinary skill in the relevant art that the present disclosure has broad utility and application. As should be understood, any embodiment may incorporate only one or a plurality of the above-disclosed aspects of the disclosure and may further incorporate only one or a plurality of the above-disclosed features. Furthermore, any embodiment discussed and identified as being “preferred” is considered to be part of a best mode contemplated for carrying out the embodiments of the present disclosure. Other embodiments also may be discussed for additional illustrative purposes in providing a full and enabling disclosure. Moreover, many embodiments, such as adaptations, variations, modifications, and equivalent arrangements, will be implicitly disclosed by the embodiments described herein and fall within the scope of the present disclosure.

Accordingly, while embodiments are described herein in detail in relation to one or more embodiments, it is to be understood that this disclosure is illustrative and exemplary of the present disclosure and are made merely for the purposes of providing a full and enabling disclosure. The detailed disclosure herein of one or more embodiments is not intended, nor is to be construed, to limit the scope of patent protection afforded in any claim of a patent issuing here from, which scope is to be defined by the claims and the equivalents thereof. It is not intended that the scope of patent protection be defined by reading into any claim a limitation found herein that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention. Accordingly, it is intended that the scope of patent protection is to be defined by the issued claim(s) rather than the description set forth herein.

Additionally, it is important to note that each term used herein refers to that which an ordinary artisan would understand such term to mean based on the contextual use of such term herein. To the extent that the meaning of a term used herein—as understood by the ordinary artisan based on the contextual use of such term—differs in any way from any particular dictionary definition of such term, it is intended that the meaning of the term as understood by the ordinary artisan should prevail.

Furthermore, it is important to note that, as used herein, “a” and “an” each generally denotes “at least one,” but does not exclude a plurality unless the contextual use dictates otherwise. When used herein to join a list of items, “or” denotes “at least one of the items,” but does not exclude a plurality of items of the list. Finally, when used herein to join a list of items, “and” denotes “all of the items of the list.”

The following detailed description refers to the accompanying drawings. Wherever possible, the same reference numbers are used in the drawings and the following description to refer to the same or similar elements. While many embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims. The present disclosure contains headers. It should be understood that these headers are used as references and are not to be construed as limiting upon the subjected matter disclosed under the header.

### Overview

According to some aspects, an OmniBUS switch is disclosed. The OmniBUS switch may be a PCIe switch capable of operating in transparent mode and/or non-transparent mode and the OmniBUS switch connects between PCIe buses either in initiator or target modes. The OmniBUS switch may assist in incrementing the number of devices that may be connected to a PCIe bus, and to add functionality supporting many modes of operation at the same time. The OmniBUS switch may switch between ports for a point-to-point connection or can work as a controlled broadcast in a point-to-multipoint environment ruled by custom headers or by a policy management controller.

In transparent mode, the OmniBUS switch may serve as an extension of the initiator PCIe bus and routes the PCIe signals to the selected target or end-point. This mode may not require any additional drivers to control the end-point PCIe device because it only acts as an extension of the bus. In non-transparent mode, the OmniBUS switch may behave like a standard network switch and it may require a driver to be able to redirect the connection to the desired device connected to the switch. One example of this driver may be a TCP/IP or IPoPCIe (IP over PCIe). In a mixed mode, the OmniBUS switch may operate in both transparent and non-transparent modes. Further, some ports may be selected for transparent and the rest for non-transparent behavior.

According to further embodiments, the OmniBUS switch may have the ability to select the ports that are involved in a point-to-multi-point transfer. This selection may be controlled either using a rules management file that controls the flow and activity of the ports or it may be controlled and over-ruled by a custom header on the transmission package. In this manner, a device may select a controlled broadcast of data only to the selected targets. The OmniBUS switch may be used for applications that benefit of having multiple copies of data with further advantage of not taking any extra transfer of data to make copies of the data.

According to some embodiments, an Intelligent PCI Express (PCIe) switch is disclosed. The Intelligent PCI Express (PCIe) provides an extension connection to PCIe devices, with software controlled capabilities for routing data and extending capabilities of a single PCIe interface. Further, support for different mode of operations provides standard features of a PCIe connection plus adding flexibility and functionality by providing non-transparent operations. Further, the presence of flexible control flow capabilities allows data to be broadcasted to selected ports using an innovative point-to-multipoint transfer technology.

Therefore, by controlling a dynamic topology of the switch and sending the transfers only to the defined ports, data is not received by unselected targets avoiding issues and unnecessary use of bandwidth. Moreover, the point to multipoint transfer requires an acknowledgment signal back from each target associated with the defined multiport transfer. If an acknowledgment is not received from a particular target, then data is re-transmitted to that specific port/target.

The present disclosure includes many aspects and features. Moreover, while many aspects and features relate to, and are described in, the context of data communication between devices, embodiments of the present disclosure are not limited to use only in this context.

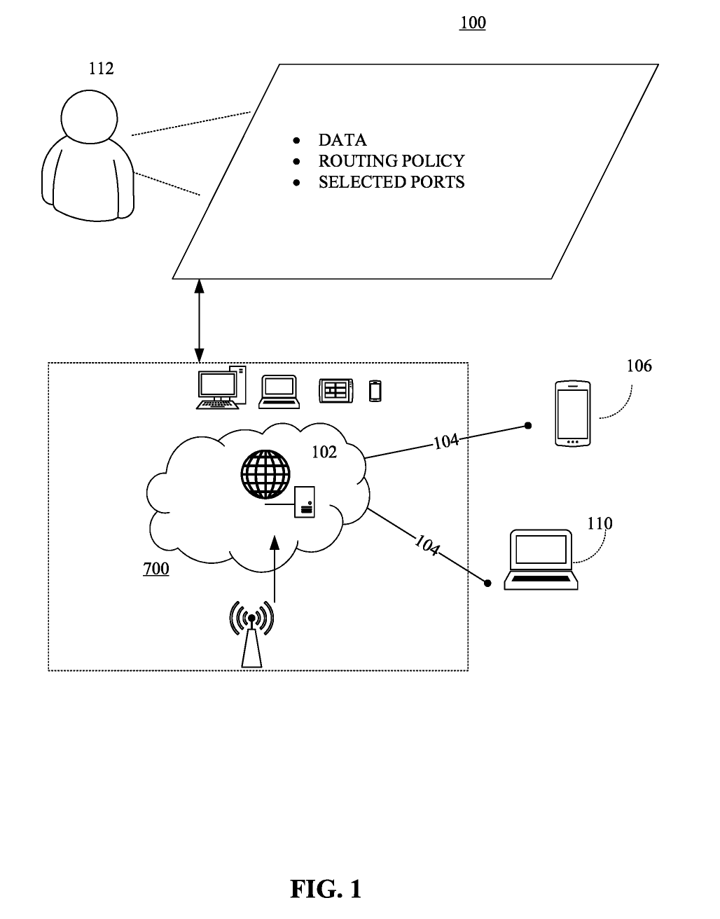

FIG. 1 is an illustration of an online platform 100 consistent with various embodiments of the present disclosure. By way of non-limiting example, the online platform 100 for facilitating communication of data may be hosted on a centralized server 102, such as, for example, a cloud computing service. The centralized server 102 may communicate with other network entities, such as, for example, a mobile device 106 (such as a smartphone, a laptop, a tablet computer etc.) and other electronic devices 110 (such as desktop computers, server computers etc.) over a communication network 104, such as, but not limited to, the Internet. Further, users of the platform may include relevant parties such as one or more of device users and administrators and so on. Accordingly, electronic devices operated by the one or more relevant parties may be in communication with the platform 100.

A user 112, such as the one or more relevant parties, may access platform 100 through a software application. The software application may be embodied as, for example, but not be limited to, a website, a web application, a desktop application, and a mobile application compatible with a computing device 700.

According to some embodiments, the online platform 100 may communicate with a switching device 200 for facilitating communication of data.

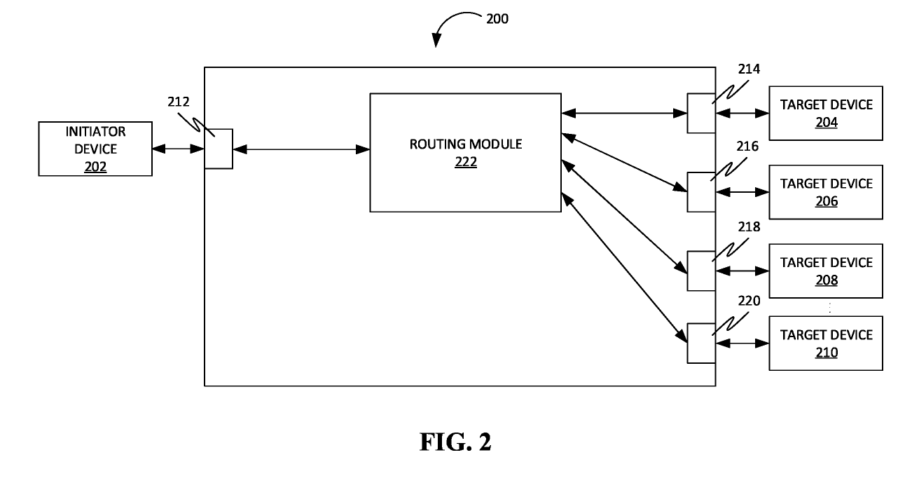

FIG. 2 is a block diagram of the switching device 200 for facilitating communication of data between at least one initiator device 202 and multiple target devices 204-210, in accordance with some embodiments. In some embodiments, the multiple target devices 204-210 may include a plurality of peripheral devices. In some embodiments, the multiple target devices 204-210 may include a plurality of storage devices.

The switching device 200 may include at least one input port 212 configured to receive the data from the at least one initiator device 202. Further, the at least one input port 212 may be communicatively coupled to at least one internal bus corresponding to the at least one initiator device 202. In some embodiments, the at least one input port 212 may include a plurality of input ports configured to receive the data from a plurality of initiator devices.

Further, the switching device 200 may include multiple output ports 214-220 configured to transmit data to the multiple target devices 204-210. Further, the multiple output ports 214-220 may be communicatively coupled to a plurality of internal buses corresponding to the multiple target devices 204-210.

In some embodiments, one or more of the at least one internal bus and the plurality of internal buses may include a Peripheral Component Interconnect Express (PCIe) bus.

In some embodiments, one or more of the at least one internal bus and the plurality of internal buses may include an optical interconnect bus.

Further, the switching device 200 may include at least one routing module 222 communicatively coupled with each of the at least one input port 212 and the multiple output ports 214-220. Further, the at least one routing module 222 may be configured to route the data from the at least one input port 212 to at least one output port of the multiple output ports 214-220. In some embodiments, the at least one routing module 222 may be further configured for analyzing a header portion of the data and identifying the at least one output port based on the analyzing. In further embodiments, the target device may be configured to embed a routing policy in the header portion. Further, the routing policy may include at least one port identifier associated with the at least one output port.

In some embodiments, the switching device 200 may further include at least one internal bus interface card configured to be coupled with a corresponding at least one card slot comprised in the at least one initiator device 202. Further, the at least one internal bus interface card facilitates a communicative coupling of the at least one input port 212 to the at least one internal bus.

In further embodiments, the at least one internal bus interface card comprises an input port configured to communicatively coupled to an internal bus. Further, the at least one internal bus interface card comprises a processing module communicatively coupled to the input port. Further, the processing module may be configured for processing the data. In some embodiments, the processing may include embedding a routing policy in a header portion of the data. In some embodiments, the routing policy may include at least one port identifier associated with the at least one output port.

Moreover, the at least one internal bus interface card comprises an output port communicatively coupled to the processing module. Further, the output port may be configured to communicate the data between the processing module and the at least one input port 212.

In some embodiments, the switching device 200 may further include a reshaping module communicatively coupled to the at least one input port 212. Further, the reshaping module may be configured to perform waveform reshaping corresponding to the data.

In some embodiments, the switching device 200 may further include a memory module communicatively coupled to the at least one routing module 222. Further, the memory module may be configured for storing a routing policy. Further, the at least one routing module 222 may be configured to route the data from the at least one input port 212 to the at least one output port of the multiple output ports 214-220 based on the routing policy.

In some embodiments, the switching device 200 may further include a control interface configured to be communicatively coupled to a remote management server. Further, the control interface may be configured to perform one or more of the transmission and the reception of the routing policy.

In some embodiments, communication of the data facilitates sharing of at least one hardware resource between the at least one initiator device 202 and at least one target device (in the multiple target devices 204-210) associated with the at least one output port (in the multiple output ports 214-220). The at least one hardware resource includes one or more of, but is not limited to, a storage device, a processing device, a networking device, an input device, and an output device.

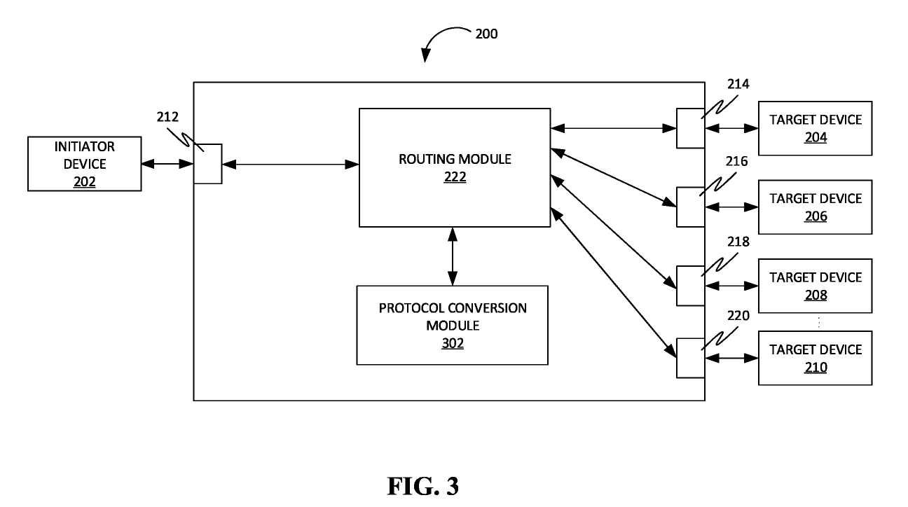

FIG. 3 is a block diagram of a switching device 200 for facilitating communication of data between at least one initiator device 202 and multiple target devices 204-210, in accordance with some embodiments. The switching device 200 may further include at least one protocol conversion module 302 communicatively coupled to each of the at least one routing module 222 and the multiple output ports 214-220. Further, the at least one protocol conversion module 302 may be configured to convert the data from at least one first protocol associated with the at least one initiator device 202 to at least one second protocol associated with at least one target device corresponding to the at least one output port. In some embodiments, the at least one first protocol may be based on PCIe and the at least one second protocol may be based on one or more of TCP/IP, or IP over PCIe (IPoPCIe).

According to some embodiments, the switching device 200 for facilitating communication of data between the at least one initiator device 202 and the multiple target devices 204-210 is disclosed. The switching device 200 may include the at least one input port 212 configured to receive the data from the at least one initiator device 202. Further, the at least one input port 212 may be communicatively coupled to the at least one internal bus corresponding to the at least one initiator device 202. Further, the switching device 200 may include the multiple output ports 214-220 configured to transmit data to the multiple target devices 204-210. Further, the multiple output ports 214-220 may be communicatively coupled to the plurality of internal buses corresponding to the multiple target devices 204-210. Further, the switching device 200 may include the at least one routing module 222 coupled with each of the at least one input port 212 and the multiple output ports 214-220. Further, the at least one routing module 222 may be configured to route the data from the at least one input port 212 to at least one output port of the multiple output ports 214-220. Further, the switching device 200 may include the at least one protocol conversion module 302 communicatively coupled to each of the at least one routing module 222 and the multiple output ports 214-220. Further, the at least one protocol conversion module 302 may be configured to convert the data from at least one first protocol associated with the at least one initiator device 202 to at least one second protocol associated with at least one target device corresponding to the at least one output port.

According to some embodiments, the switching device 200 for facilitating communication of data between at least the one initiator device 202 and the multiple target devices 204-210 is disclosed. The switching device 200 may include the at least one input port 212 configured to receive the data from the at least one initiator device 202. Further, the at least one input port 212 may be communicatively coupled to at least one PCIe bus corresponding to the at least one initiator device 202. Further, the switching device 200 may include the multiple output ports 214-220 configured to transmit data to the multiple target devices 204-210. Further, the multiple output ports 214-220 may be communicatively coupled to a plurality of PCIe buses corresponding to the multiple target devices 204-210. Moreover, the switching device 200 may include at least one routing module 222 communicatively coupled with each of the at least one input port 212 and the multiple output ports 214-220. Further, the at least one routing module 222 may be configured to route the data from the at least one input port 212 to at least one output port of the multiple output ports 214-220.

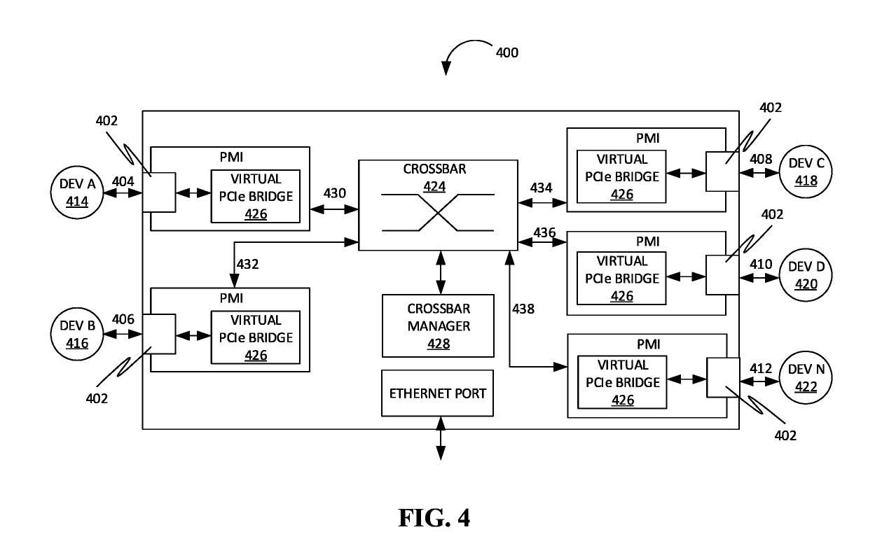

FIG. 4 is a block diagram of an OmniBUS PCIe Switch 400 for facilitating communication of data, in accordance with some embodiments. The OmniBUS PCIe Switch 400 may be composed of a single Integrated Circuit, a FPGA (Field Programmable Gate Array) or by using standard electronic components. The OmniBUS PCIe Switch 400 may include multiple ports 402 that may be configured as Upstream or Downstream for transparent mode and both for Non-Transparent Ports (NTP). The multiple ports 402 may include a Serializer/Deserializer (SerDes) for use with PCIe signals. The multiple ports 402 may be connected to the PCIe busses 404-412 coming from the external devices 414-422. The multiple ports 402 may be connected to a crossbar 424 through virtual PCIe Bridges 426 or re-timers. The virtual PCIe Bridges 426 may extend the PCIe bus and reshape the waveforms and timings of the signals. Further, a Crossbar Manager 428 may map the passages of crossbar locations inside the Crossbar 424 acting as a switch and controlling the interconnection of the PCIe internal buses 430-438.

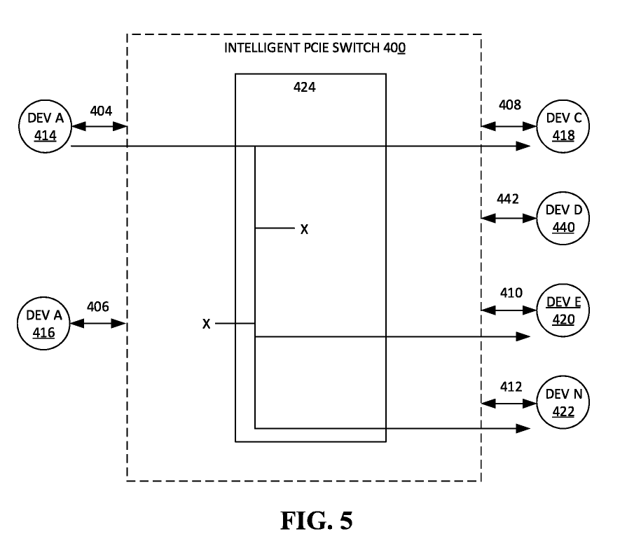

FIG. 5 is a block diagram of the OmniBUS PCIe Switch 400 facilitating intelligent point-to-multipoint data transfer according to some embodiments. A point-to-multipoint sequence may be generated by the external device 414 and may be sent to the OmniBUS PCIe Switch 400 through the PCIe bus 404. The crossbar 424 may be dynamically selected to map the incoming signals to several selected ports to pass-through the incoming signals. The data may be sent to PCIe buses 408, 410 and 412 but not to PCIe buses 406 and 442 because they do not consist of the point-to-multipoint transfer operation. The PCIe bus 442 may be connected to a device 440. The same data may be sent through the PCIe buses 408, 410 and 412 and to the respective attached devices 418-422.

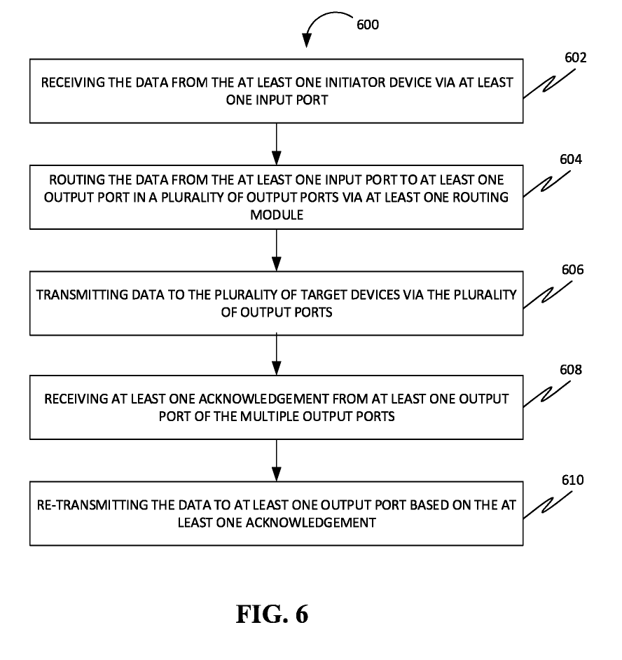

FIG. 6 is a flowchart of a method 600 of facilitating communication of data between at least one initiator device (such as the at least one initiator device 202) and multiple target devices ((such as the multiple target devices 204-210), in accordance with some embodiments. At 602, the method 600 includes receiving the data from the at least one initiator device via at least one input port (such as the at least one input port 212). The at least one input port may be communicatively coupled to at least one internal bus corresponding to the at least one initiator device.

At 604, the method 600 includes routing the data from the at least one input port to at least one output port in multiple output ports (such as the multiple output ports 214-220) via at least one routing module (such as the at least one routing module 222). The at least one routing module may be communicatively coupled with each of the at least one input port and the multiple output ports. The at least one routing module may be further configured for analyzing a header portion of the data and identifying the at least one output port based on the analyzing. In some embodiments, the routing the data from the at least one input port to the at least one output port of the multiple output ports may be based on a routing policy.

At 606, the method 600 includes transmitting data to the plurality of target devices via the multiple output ports. The multiple output ports may be communicatively coupled to a plurality of internal buses corresponding to the plurality of target devices.

At 608, the method 600 includes receiving at least one acknowledgement from at least one output port of the multiple output ports. At 610, the method 600 includes re-transmitting the data to at least one output port based on the at least one acknowledgement. Accordingly, when acknowledgment is not received from an output port, the data is re-transmitted to that output port.

In further embodiments, the method 600 may include converting the data from at least one first protocol associated with the at least one initiator device to at least one second protocol associated with at least one target device corresponding to the at least one output port. The converting the data may be performed by the at least one protocol conversion module communicatively coupled to each of the at least one routing module and the multiple output ports. The at least one first protocol may be based on PCIe and the at least one second protocol is based on at least one of TCP/IP or IP over PCIe (IPoPCIe).

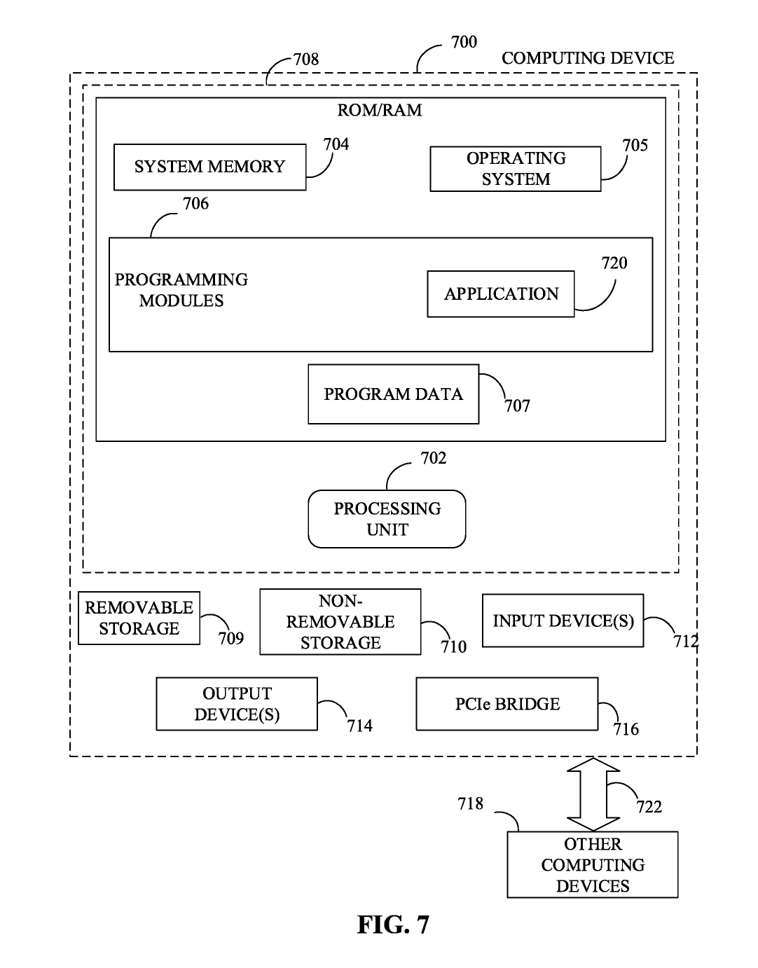

FIG. 7 is a block diagram of a computing device for implementing the methods disclosed herein, in accordance with some embodiments. Consistent with an embodiment of the disclosure, the aforementioned storage device and processing device may be implemented in a computing device, such as computing device 700 of FIG. 7. Any suitable combination of hardware, software, or firmware may be used to implement the memory storage and processing unit. For example, the storage device and the processing device may be implemented with computing device 700 or any of other computing devices 718, in combination with computing device 700. The aforementioned system, device, and processors are examples and other systems, devices, and processors may comprise the aforementioned storage device and processing device, consistent with embodiments of the disclosure.

With reference to FIG. 7, a system consistent with an embodiment of the disclosure may include a computing device or cloud service, such as computing device 700. In a basic configuration, computing device 700 may include at least one processing unit 702 and a system memory 704. Depending on the configuration and type of computing device, system memory 704 may comprise, but is not limited to, volatile (e.g. random access memory (RAM)), non-volatile (e.g. read-only memory (ROM)), flash memory, or any combination. System memory 704 may include operating system 705, one or more programming modules 706, and may include a program data 707. Operating system 705, for example, may be suitable for controlling computing device 700's operation. Furthermore, embodiments of the disclosure may be practiced in conjunction with a graphics library, other operating systems, or any other application program and is not limited to any particular application or system. This basic configuration is illustrated in FIG. 7 by those components within a dashed line 708.

Computing device 700 may have additional features or functionality. For example, computing device 700 may also include additional data storage devices (removable and/or non-removable) such as, for example, magnetic disks, optical disks, or tape. Such additional storage is illustrated in FIG. 7 by a removable storage 709 and a non-removable storage 710. Computer storage media may include volatile and nonvolatile, removable and non-removable media implemented in any method or technology for storage of information, such as computer-readable instructions, data structures, program modules, or other data. System memory 704, removable storage 709, and non-removable storage 710 are all computer storage media examples (i.e., memory storage.) Computer storage media may include, but is not limited to, RAM, ROM, electrically erasable read-only memory (EEPROM), flash memory or other memory technology, CD-ROM, digital versatile disks (DVD) or other optical storage, magnetic cassettes, magnetic tape, magnetic disk storage or other magnetic storage devices, or any other medium which can be used to store information and which can be accessed by computing device 700. Any such computer storage media may be part of device 700. Computing device 700 may also have input device(s) 712 such as a keyboard, a mouse, a pen, a sound input device, a touch input device, etc. Output device(s) 714 such as a display, speakers, a printer, etc. may also be included. The aforementioned devices are examples and others may be used.

Computing device 700 may also contain a PCIe Bridge 716 as a communication connection that may allow device 700 to communicate with other computing devices 718, such as over a PCIe network 722 in a distributed computing environment, for example, an intranet. The PCIe Bridge 716 may be the Communication connection. The PCIe network 722 (either point to point or using the PCIe switch) serves as an extension of one Computer Device internal bus, interconnecting all PCIe busses from other Computing devices. This OmniBUS interconnection allows sharing resources on a PCIe Computer Device cluster.

The communication type of the PCIe Bridge 716 is one example of communication media. Communication media may typically be embodied by computer readable instructions, data structures, program modules, or other data in a modulated data signal, such as a carrier wave or other transport mechanism, and includes any information delivery media. The term “modulated data signal” may describe a signal that has one or more characteristics set or changed in such a manner as to encode information in the signal. By way of example, and not limitation, communication media may include wired media such as a wired network or direct-wired connection, optical, and wireless media such as acoustic, radio frequency (RF), infrared, and other wireless media. The term computer readable media as used herein may include both storage media and communication media.

As stated above, a number of program modules and data files may be stored in system memory 704, including operating system 705. While executing on processing unit 702, programming modules 706 (e.g., application 720) may perform processes including, for example, one or more stages of method 600, algorithms, switching device 200, applications, servers, databases as described above. The aforementioned process is an example, and processing unit 702 may perform other processes. Other programming modules that may be used in accordance with embodiments of the present disclosure may include sound encoding/decoding applications, machine learning application, acoustic classifiers etc.

Further, in some embodiments, there may be two or more instantiations of the computing device 700. Further, a first instantiation of the computing device 700 may be configured to perform a communication with the second instantiation of the computing device 700. Furthermore, the communication may be performed using a bridge (e.g. the PCIe bridge 716) configured to communicatively couple a first internal bus of the first instantiation of the computing device 700 with a second internal bus of the second instantiation of the computing device 700. Further, in some embodiments, each of the first instantiation of the computing device 700 and the second instantiation of the computing device 700 may include an instantiation of the bridge (e.g. the PCIe bridge 716). Further, in some embodiments, the second instantiation of the computing device 700 may include a plurality of second instantiations of the computing device 700. In other words, the first instantiation of the computing device 700 (i.e. the initiator device) may be capable of performing the communication with multiple second instantiations of the computing device 700 (i.e. multiple target devices) in accordance with the method described in conjunction with FIG. 6.

Generally, consistent with embodiments of the disclosure, program modules may include routines, programs, components, data structures, and other types of structures that may perform particular tasks or that may implement particular abstract data types. Moreover, embodiments of the disclosure may be practiced with other computer system configurations, including hand-held devices, multiprocessor systems, microprocessor-based or programmable consumer electronics, minicomputers, mainframe computers, and the like. Embodiments of the disclosure may also be practiced in distributed computing environments where tasks are performed by remote processing devices that are linked through a communications network. In a distributed computing environment, program modules may be located in both local and remote memory storage devices.

Furthermore, embodiments of the disclosure may be practiced in an electrical circuit comprising discrete electronic elements, packaged or integrated electronic chips containing logic gates, a circuit utilizing a microprocessor, or on a single chip containing electronic elements or microprocessors. Embodiments of the disclosure may also be practiced using other technologies capable of performing logical operations such as, for example, AND, OR, and NOT, including but not limited to mechanical, optical, fluidic, and quantum technologies. In addition, embodiments of the disclosure may be practiced within a general purpose computer or in any other circuits or systems.

Embodiments of the disclosure, for example, may be implemented as a computer process (method), a computing system, or as an article of manufacture, such as a computer program product or computer readable media. The computer program product may be a computer storage media readable by a computer system and encoding a computer program of instructions for executing a computer process. The computer program product may also be a propagated signal on a carrier readable by a computing system and encoding a computer program of instructions for executing a computer process. Accordingly, the present disclosure may be embodied in hardware and/or in software (including firmware, resident software, micro-code, etc.). In other words, embodiments of the present disclosure may take the form of a computer program product on a computer-usable or computer-readable storage medium having computer-usable or computer-readable program code embodied in the medium for use by or in connection with an instruction execution system. A computer-usable or computer-readable medium may be any medium that can contain, store, communicate, propagate, or transport the program for use by or in connection with the instruction execution system, apparatus, or device.

The computer-usable or computer-readable medium may be, for example but not limited to, an electronic, magnetic, optical, electromagnetic, infrared, or semiconductor system, apparatus, device, or propagation medium. More specific computer-readable medium examples (a non-exhaustive list), the computer-readable medium may include the following: an electrical connection having one or more wires, a portable computer diskette, a random access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

What is claimed is:

1. A switching device for facilitating communication of data between at least one initiator device and a plurality of target devices, the switching device comprising:
at least one input port configured to receive the data from the at least one initiator device, wherein the at least one input port is communicatively coupled to at least one internal bus corresponding to the at least one initiator device;
a plurality of output ports configured to transmit data to the plurality of target devices, wherein the plurality of output ports is communicatively coupled to a plurality of internal buses corresponding to the plurality of target devices; and
at least one routing module communicatively coupled with each of the at least one input port and the plurality of output ports, wherein the at least one routing module is configured to route the data from the at least one input port to at least one output port of the plurality of output ports.

2. The switching device of claim 1, wherein at least one of the at least one internal bus and the plurality of internal buses comprises a Peripheral Component Interconnect Express (PCIe) bus and an optical interconnect bus.

3. The switching device of claim 1 further comprising at least one protocol conversion module communicatively coupled to each of the at least one routing module and the plurality of output ports, wherein the at least one protocol conversion module is configured to convert the data from at least one first protocol associated with the at least one initiator device to at least one second protocol associated with at least one target device corresponding to the at least one output port.

4. The switching device of claim 3, wherein the at least one first protocol is based on PCIe and the at least one second protocol is based on at least one of TCP/IP and IP over PCIe (IPoPCIe).

5. The switching device of claim 1, wherein the at least one routing module is further configured for:
analyzing a header portion of the data; and
identifying the at least one output port based on the analyzing.

6. The switching device of claim 5, wherein the target device is configured to embed a routing policy in the header portion.

7. The switching device of claim 6, wherein the routing policy comprises at least one port identifier associated with the at least one output port.

8. The switching device of claim 1, wherein the plurality of target devices comprises a plurality of peripheral devices.

9. The switching device of claim 1, wherein the plurality of target devices comprises a plurality of storage devices.

10. The switching device of claim 1 further comprising at least one internal bus interface card configured to be coupled with a corresponding at least one card slot comprised in the at least one initiator device, wherein the at least one internal bus interface card facilitates communicative coupling of the at least one input port to the at least one internal bus.

11. The switching device of claim 10, wherein the at least one internal bus interface card comprises:
an input port configured to communicatively coupled to an internal bus;
a processing module communicatively coupled to the input port, wherein the processing module is configured for processing the data; and
an output port communicatively coupled to the processing module, wherein the output port is further configured to communicate the data between the processing module and the at least one input port.

12. The switching device of claim 11, wherein the processing comprises embedding a routing policy in a header portion of the data.

13. The switching device of claim 12, wherein the routing policy comprises at least one port identifier associated with the at least one output port.

14. The switching device of claim 1 further comprising a reshaping module communicatively coupled to the at least one input port, wherein the reshaping module is configured to perform waveform reshaping corresponding to the data.

15. The switching device of claim 1, wherein the at least one input port comprises a plurality of input ports configured to receive the data from a plurality of initiator devices.

16. The switching device of claim 1 further comprising a memory module communicatively coupled to the at least one routing module, wherein the memory module is configured for storing a routing policy, wherein the at least one routing module is configured to route the data from the at least one input port to the at least one output port of the plurality of output ports based on the routing policy.

17. The switching device of claim 16 further comprises a control interface configured to be communicatively coupled to a remote management server, wherein the control interface is configured to perform at least one of transmission and reception of the routing policy.

18. The switching device of claim 1, wherein communication of the data facilitates sharing of at least one hardware resource between the at least one initiator device and at least one target device associated with the at least one output port.

19. A switching device for facilitating communication of data between at least one initiator device and a plurality of target devices, the switching device comprising:
at least one input port configured to receive the data from the at least one initiator device, wherein the at least one input port is communicatively coupled to at least one internal bus corresponding to the at least one initiator device;
a plurality of output ports configured to transmit data to the plurality of target devices, wherein the plurality of output ports is communicatively coupled to a plurality of internal buses corresponding to the plurality of target devices;
at least one routing module coupled with each of the at least one input port and the plurality of output ports, wherein the at least one routing module is configured to route the data from the at least one input port to at least one output port of the plurality of output ports; and
at least one protocol conversion module communicatively coupled to each of the at least one routing module and the plurality of output ports, wherein the at least one protocol conversion module is configured to convert the data from at least one first protocol associated with the at least one initiator device to at least one second protocol associated with at least one target device corresponding to the at least one output port.

20. A switching device for facilitating communication of data between at least one initiator device and a plurality of target devices, the switching device comprising:
at least one input port configured to receive the data from the at least one initiator device, wherein the at least one input port is communicatively coupled to at least one PCIe bus corresponding to the at least one initiator device;
a plurality of output ports configured to transmit data to the plurality of target devices, wherein the plurality of output ports is communicatively coupled to a plurality of PCIe buses corresponding to the plurality of target devices;
at least one routing module communicatively coupled with each of the at least one input port and the plurality of output ports, wherein the at least one routing module is configured for:
routing the data from the at least one input port to at least one output port of the plurality of output ports;
receiving at least one acknowledgement from the at least one output port; and
re-transmitting the data to the at least one output port based on receiving the at least one acknowledgement.
